(19) United States
(12) Patent Application Publication
(10) Pub. No.: US 2006/0197260 A1
(43) Pub. Date: Sep. 7, 2006

(54) Laser processing method and laser beam processing machine

(75) Inventors: Toshiyuki Yoshikawa, Tokyo (JP); Koichi Shigematsu, Tokyo (JP)

Correspondence Address: SMITH, GAMBRELL & RUSSELL, 1850 M STREET, N.W., SUITE 800, WASHINGTON, DC, 20036, US

(73) Assignee: Disco Corporation

(21) Appl. No.: 11/365,833

(22) Filed: Mar. 2, 2006

(30) Foreign Application Priority Data
Mar. 7, 2005 (JP) 2005-062145

(51) Int. Cl. H01L 21/78; H05B 6/00

(52) U.S. Cl. 264/482; 438/463

(57) ABSTRACT

A laser processing method for melt-dividing an adhesive film for die bonding affixed to the back surface of a semiconductor wafer which has been separated into a plurality of semiconductor chips and which is put on an extensible dicing tape mounted on an annular frame along dividing grooves for separating the plurality of semiconductor chips from one another, comprising the steps of a tape expanding step for expanding the dicing tape affixed to the semiconductor wafer to increase the width of the dividing grooves for separating the plurality of semiconductor chips from one another; and an adhesive film melt-dividing step for melt-dividing the adhesive film along the dividing grooves by applying a laser beam to the adhesive film along the dividing grooves in a state where the width of the dividing grooves for separating the plurality of semiconductor chips from one another has been increased.

### FIELD OF THE INVENTION

The present invention relates to a laser processing method for melt-dividing an adhesive film for die bonding, which is affixed to the back surface of a semiconductor wafer that has been separated into a plurality of semiconductor chips, and to a laser beam processing machine.

### DESCRIPTION OF THE PRIOR ART

In the manufacturing process of a semiconductor device, for example, individual semiconductor chips are manufactured by forming a device such as IC or LSI in a plurality of areas sectioned by streets (cutting lines) formed in a lattice pattern on the front surface of a substantially disk-like semiconductor wafer and dividing the semiconductor wafer into the areas having device formed thereon, along the streets. A dicing machine is generally used as the dividing machine for dividing the semiconductor wafer to cut the semiconductor wafer along the streets with a cutting blade having a thickness of about 20 μm. The thus obtained semiconductor chips are packaged and widely used in electric appliances such as mobile phones and personal computers.

An adhesive film for die bonding called “die attach film” having a thickness of 20 to 40 μm and made of a polyimide-based resin, epoxy-based resin or acrylic resin is mounted onto the back surfaces of the above individually divided semiconductor chips, and these semiconductor chips are then bonded to a die bonding frame for supporting the semiconductor chips via this adhesive film, by heating. To mount the adhesive film for die bonding onto the back surfaces of the semiconductor chips, after the adhesive film is affixed to the back surface of the semiconductor wafer and the semiconductor wafer is put on a dicing tape via this adhesive film, the semiconductor wafer is cut together with the adhesive film along the streets formed on the front surface of the semiconductor wafer with a cutting blade to obtain semiconductor chips having the adhesive film on the back surface, as disclosed by JP-A 2000-182995, for example.

According to the method disclosed by JP-A 2000-182995, however, when the adhesive film is cut together with the semiconductor wafer with the cutting blade to divide the semiconductor wafer into individual semiconductor chips, the back surfaces of the semiconductor chips may have chips or the adhesive film may have whisker-like burrs to cause disconnection at the time of wire bonding.

Lighter and smaller electric appliances such as mobile phones and personal computers are now in growing demand and therefore, thinner semiconductor chips are desired. A dividing technique so called “pre-dicing” is used to divide a semiconductor wafer into thinner semiconductor chips. In this pre-dicing technique, dividing grooves having a predetermined depth (corresponding to the final thickness of each semiconductor chip) are formed on the front surface of the semiconductor wafer along the streets and exposed to the back surface by grinding the back surface of the semiconductor wafer having the dividing grooves formed on the front surface to divide the semiconductor wafer into individual semiconductor chips. This technique makes it possible to process each semiconductor chip to a thickness of 50 μm or less.

However, as when the semiconductor wafer is divided into individual semiconductor chips by the pre-dicing technique, after the dividing grooves having a predetermined depth are formed on the front surface of the semiconductor wafer along the streets, the back surface of the semiconductor wafer is ground to expose the dividing grooves to the back surface, the adhesive film for die bonding cannot be mounted on the back surface of the semiconductor wafer beforehand. Accordingly, to bond the semiconductor chips to the die bonding frame for supporting the semiconductor chips in the pre-dicing technique, a bonding agent must be inserted between the semiconductor chips and the die bonding frame, thereby making it impossible to carry out the bonding work smoothly.

To solve the above problem, JP-A 2002-118081 discloses a semiconductor manufacturing process comprising affixing an adhesive film for die bonding to the back surfaces of semiconductor chips obtained by pre-dicing a semiconductor wafer, bonding the semiconductor chips to a dicing tape via this adhesive film and then, applying a laser beam to a portion of the adhesive film exposed from gaps between adjacent semiconductor chips from the front surfaces of the semiconductor chips through the gaps to remove the portions exposed from the gaps of the adhesive film.

The technology disclosed by JP-A 2002-118081 is to apply a laser beam to dividing grooves formed with a cutting blade having a thickness of about 20 μm from the front surfaces of the semiconductor chips to melt-divide the portions exposed from the gaps between adjacent semiconductor chips of the adhesive film. However, it is difficult to melt-divide only the adhesive film without applying a laser beam to the front surfaces of the semiconductor chips. Particularly, when the dividing grooves are shifted at the time of grinding the back surface of the semiconductor wafer by pre-dicing, it is difficult to fuse only the adhesive film without applying a laser beam to the front surfaces of the semiconductor chips. Therefore, in the semiconductor chip manufacturing process disclosed by the above publication, the front surfaces of the semiconductor chips having a device formed thereon may be damaged by the laser beam.

To solve the above problem, the applicant company of the present application proposes in JP-A 2003-348277 and discloses in JP-A 2005-116739 a semiconductor chip manufacturing process comprising affixing an adhesive film for die bonding to the back surface of a semiconductor wafer which has been divided into individual semiconductor chips by pre-dicing, putting the adhesive film side of the semiconductor wafer on a dicing tape and then, applying a laser beam having a wavelength absorbed by the adhesive film but not by the dicing tape along the dividing grooves from the dicing tape side to melt-divide the adhesive film along the dividing grooves.

In the semiconductor manufacturing process disclosed by the above JP-A 2005-116739, however, a problem arose that debris produced when the adhesive film has been molten by the application of a laser beam entered a dividing groove, and the divided semiconductor chips were bonded together by the debris, thereby making it difficult to pick up the semiconductor chips. Further, as the width of the above dividing grooves is small, the laser beam may be applied to the back surface of a semiconductor chip, thereby reducing the quality of the semiconductor chip.

### SUMMARY OF THE INVENTION

It is an object of the present invention to provide a laser processing method and a laser beam processing machine capable of melt-dividing an adhesive film affixed to the back surface of a semiconductor wafer which has been divided into individual semiconductor chips without being influenced by debris produced when the adhesive film is molten by the application of a laser beam.

To attain the above object, according to the present invention, there is provided a laser processing method for melt-dividing an adhesive film for die bonding affixed to the back surface of a semiconductor wafer which has been separated into a plurality of semiconductor chips and which is put on an extensible dicing tape mounted on an annular frame along dividing grooves for separating the plurality of semiconductor chips from one another, comprising the steps of:

a tape expanding step for expanding the dicing tape affixed to the semiconductor wafer to increase the width of the dividing grooves for separating the plurality of semiconductor chips from one another; and

an adhesive film melt-dividing step for melt-dividing the adhesive film along the dividing grooves by applying a laser beam to the adhesive film along the dividing grooves in a state where the width of the dividing grooves for separating the plurality of semiconductor chips from one another has been increased.

Further, according to the present invention, there is provided a laser beam processing machine comprising a chuck table mechanism for holding a workpiece put on a dicing tape mounted on an annular frame, a laser beam application means for applying a laser beam to the workpiece held on the chuck table mechanism, and a processing-feed means for moving the laser beam application means and the chuck table relative to each other, wherein

the chuck table mechanism comprises a chuck table for holding the workpiece, a frame holding means for holding the annular frame, which is arranged around the chuck table, and a moving means for moving the frame holding means and the chuck table relative to each other in the axial direction.

According to the present invention, since a laser beam is applied to the adhesive film along the dividing grooves in a state where the dicing tape affixed to the semiconductor wafer has been expanded to increase the width of the dividing grooves for separating the plurality of semiconductor chips from one another so as to expand the interval between adjacent semiconductor chips when the adhesive film for die bonding, which is affixed to the back surface of the semiconductor wafer that has been divided into the plurality of semiconductor chips is to be melt-divided, even if the adhesive film is molten at the time of melt-dividing the adhesive film, semiconductor chips are not bonded together by the molten adhesive film. Further, since the width of the dividing grooves of the semiconductor wafer is increased to expand the interval between adjacent semiconductor chips as described above in the adhesive film melt-dividing step, the laser beam is not applied to the semiconductor chips.

### BRIEF DESCRIPTION OF THE DRAWINGS

FIG. 1 is a perspective view of a semiconductor wafer to be divided by the semiconductor chip manufacturing process;

FIGS. 2(a) and 2(b) are explanatory diagrams showing the dividing groove forming step in the semiconductor chip manufacturing process;

FIGS. 3(a) and 3(b) are explanatory diagrams showing the protective member affixing step in the semiconductor chip manufacturing process;

FIGS. 4(a), 4(b) and 4(c) are explanatory diagrams showing the dividing groove exposing step in the semiconductor chip manufacturing process;

FIGS. 5(a) and 5(b) are diagrams showing the adhesive film affixing step in the semiconductor chip manufacturing process;

FIGS. 6(a) and 6(b) are explanatory diagrams showing the dicing tape affixing step in the semiconductor chip manufacturing process;

FIGS. 7(a) and 7(b) are explanatory diagrams showing another example of the adhesive film affixing step in the semiconductor chip manufacturing process;

FIG. 8 is a schematic perspective view of a laser beam processing machine for carrying out the adhesive film melt-dividing step in the laser processing method of the present invention;

FIG. 9 is a perspective view of a chuck table installed in the laser beam processing machine shown in FIG. 8;

FIG. 10 is a sectional view of the chuck table shown in FIG. 9;

FIGS. 11(a) and 11(b) are explanatory diagrams showing the tape expanding step in the laser processing method of the present invention;

FIG. 12 is an explanatory diagram showing the adhesive film melt-dividing step in the laser processing method of the present invention;

FIG. 13 is an enlarged sectional view showing a state where the adhesive film has been melt-divided by the adhesive film melt-dividing step;

FIG. 14 is an explanatory diagram showing the protective member removing step in the semiconductor chip manufacturing process;

FIG. 15 is a perspective view of a pick-up apparatus for carrying out the semiconductor chip removing step in the semiconductor chip manufacturing process;

FIGS. 16(a) and 16(b) are explanatory diagrams showing the semiconductor chip removing step in the semiconductor chip manufacturing process;

FIG. 17 is a perspective view of a semiconductor chip formed by the semiconductor chip manufacturing process;

FIG. 18 is an explanatory diagram showing another example of the dicing tape affixing step in the semiconductor chip manufacturing process;

FIG. 19 is an explanatory diagram showing another example of the adhesive film melt-dividing step in the laser processing method of the present invention;

FIG. 20 is an enlarged section view showing a state where the adhesive film has been melt-divided by the adhesive film melt-dividing step shown in FIG. 19;

FIG. 21 is an explanatory diagram showing still another example of the dicing tape affixing step in the semiconductor chip manufacturing process;

FIG. 22 is an explanatory diagram showing still another example of the adhesive film melt-dividing step in the laser processing method of the present invention; and

FIG. 23 is an enlarged sectional view showing that adhesive film has been melt-divided by the adhesive film melt-dividing step shown in FIG. 22.

### DETAILED DESCRIPTION OF THE PREFERRED EMBODIMENTS

Preferred embodiments of the laser processing method and the laser beam processing machine of the present invention will be described in detail hereinunder with reference to the accompanying drawings.

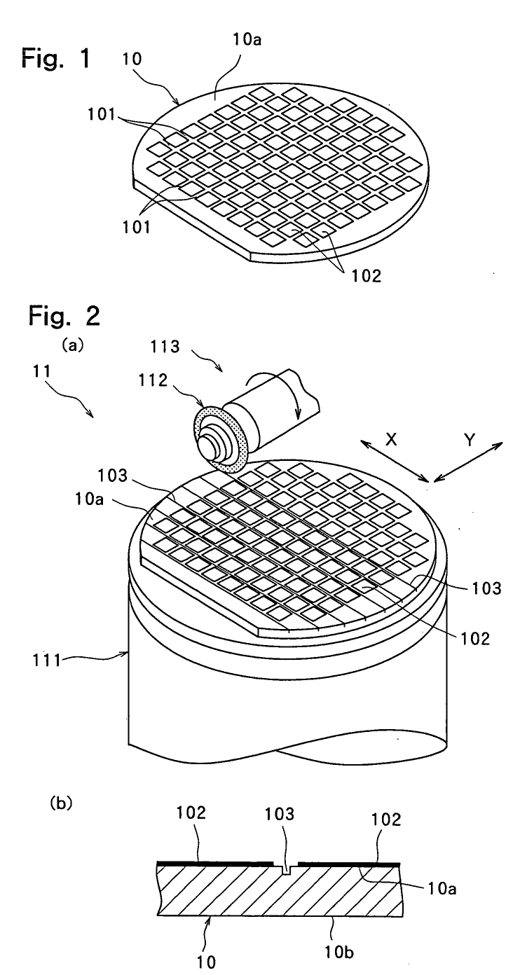

FIG. 1 is a perspective view of a semiconductor wafer to be divided into a plurality of semiconductor chips. The semiconductor wafer 10 shown in FIG. 1 is, for example, a silicon wafer having a thickness of 600 μm, a plurality of streets 101 are formed in a lattice pattern on the front surface 10a, and a device 102 is formed in each of a plurality of areas sectioned by the plurality of streets 101. The process for manufacturing semiconductor chips by dividing this semiconductor wafer 10 into individual semiconductor chips will be described hereinunder.

To divide the semiconductor wafer 10 into individual semiconductor chips, dividing grooves having a predetermined depth (corresponding to the final thickness of each semiconductor chip) are first formed along the streets 101 formed on the front surface 10a of the semiconductor wafer 10 (dividing groove forming step). A cutting machine 11, which is commonly used as a dicing machine shown in FIG. 2(a), may be used in this dividing groove forming step. That is, the cutting machine 11 comprises a chuck table 111 having a suction-holding means and a cutting means 113 having a cutting blade 112. The semiconductor wafer 10 is held on the chuck table 111 of this cutting machine 11 in such a manner that the front surface 10a of the semiconductor wafer 10 faces up, and the chuck table 111 is moved in a cutting-feed direction indicated by an arrow X while the cutting blade 112 of the cutting means 113 is rotated to form a dividing groove 103 along a street 101 extending in a predetermined direction. The dividing groove 103 has a depth (for example, 110 μm) corresponding to the final thickness of each semiconductor chip as shown in FIG. 2(b). After the dividing groove 103 is thus formed along the street 101 extending in the predetermined direction, the cutting means 113 is moved by a distance corresponding to the interval between adjacent streets 101 in an indexing-feed direction indicated by an arrow Y to carry out the above cutting-feeding again. After the above cutting-feeding and indexing-feed are carried out on all the streets 101 extending in the predetermined direction, the chuck table 111 is turned at 90° to carry out the above cutting-feeding and indexing-feed on streets 101 extending in a direction perpendicular to the above predetermined direction, thereby forming dividing grooves 103 along all the streets 101 formed on the semiconductor wafer 10.

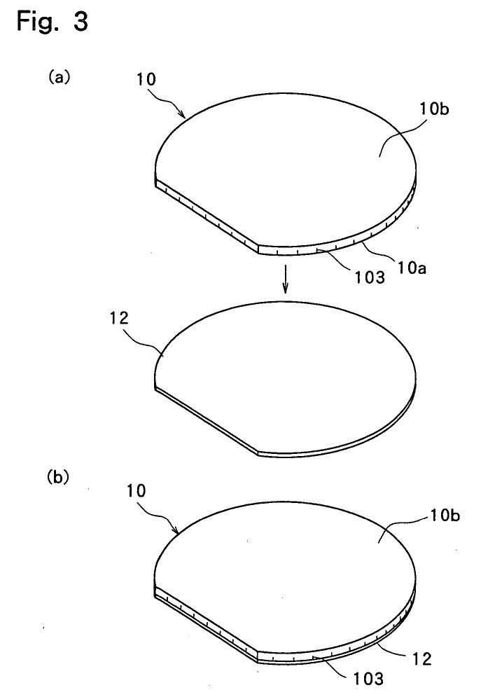

After the dividing grooves 103 having a predetermined depth are formed along the streets 101 on the front surface 10a of the semiconductor wafer 10 in the above dividing groove forming step, a protective member 12 for grinding is affixed to the front surface 10a (that is the surface on which the device 102 is formed) of the semiconductor wafer 10 as shown in FIG. 3(a) and FIG. 3(b) (protective member affixing step). A polyolefin sheet having a thickness of 150 μm is used as the protective member 12 in the illustrated embodiment.

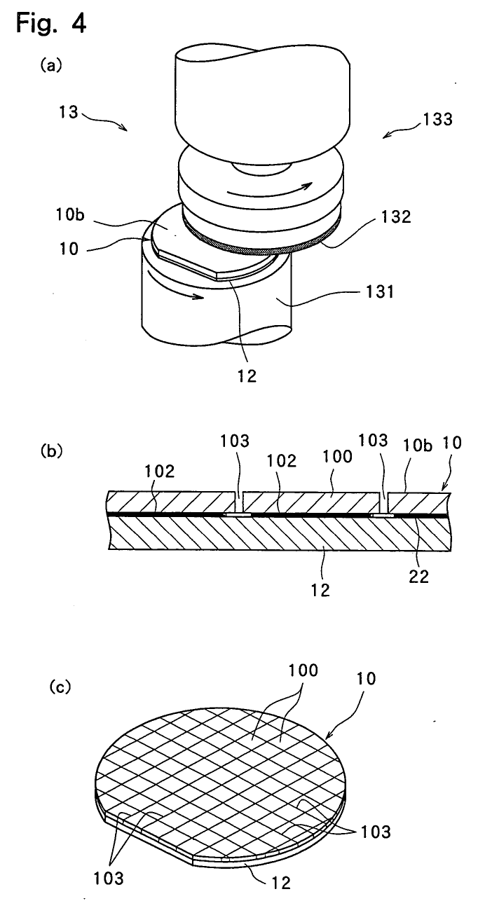

Thereafter, the back surface 10b of the semiconductor wafer 10 having the protective member 12 affixed to the front surface 10a is ground to expose the dividing grooves 103 to the back surface 10b, thereby dividing the semiconductor wafer 10 into individual semiconductor chips (dividing groove exposing step). This dividing groove exposing step is carried out by a grinder 13 equipped with a chuck table 131 and a grinding means 133 having a grindstone 132 as shown in FIG. 4(a). That is, the semiconductor wafer 10 is held on the chuck table 131 in such a manner that the back surface 10b faces up, and the grindstone 132 of the grinding means 133 is rotated at 6,000 rpm and is brought into contact with the back surface 10b of the semiconductor wafer 10 while the chuck table 131 is rotated at 300 rpm, for example, to grind the back surface 10b until the dividing grooves 103 are exposed to the back surface 10b as shown in FIG. 4(b). By thus grinding until the dividing grooves 103 are exposed, the semiconductor wafer 10 is separated into individual semiconductor chips 100 as shown in FIG. 4(c). Since the separated semiconductor chips 100 have the protective member 12 affixed to the front surfaces thereof, they do not fall apart and the form of the semiconductor wafer 10 is maintained.

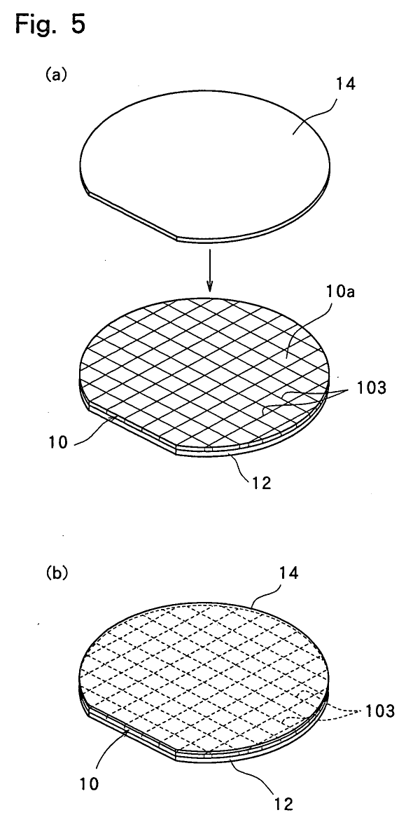

After the semiconductor wafer 10 is separated into the individual semiconductor chips 100 by the above dividing groove exposing step, next comes the step of affixing an adhesive film to the back surface 10b of the semiconductor wafer 10 separated into individual semiconductor chips. That is, as shown in FIGS. 5(a) and 5(b), the adhesive film 14 is affixed onto the back surface 10b of the semiconductor wafer 10 separated into individual semiconductor chips. At this point, the adhesive film 14 is pressed against the back surface 10b of the semiconductor wafer 10 under heating at 80 to 200° C. to be affixed to the back surface 10b. The adhesive film 14 is made of a polyimide-based resin, epoxy-based resin or acrylic resin and has a thickness of 25 μm.

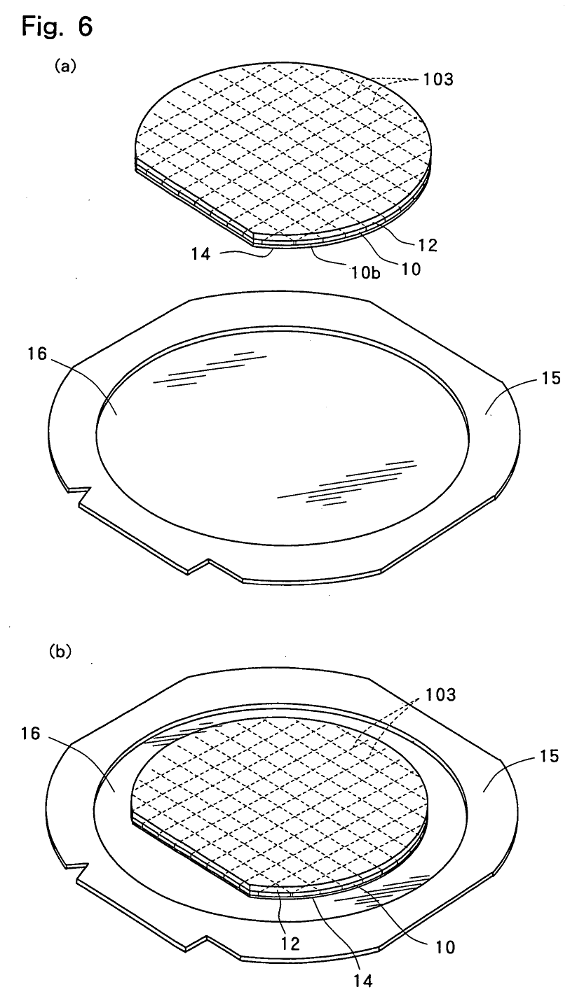

The above adhesive film affixing step is followed by the step of putting the adhesive film 14 side of the semiconductor wafer 10 having the adhesive film 14 affixed thereto on an extensible dicing tape mounted on an annular frame. That is, as shown in FIGS. 6(a) and 6(b), the adhesive film 14 side of the semiconductor wafer 10 is put on the surface of the dicing tape 16 whose peripheral portion is mounted on the annular dicing frame 15 so as to cover its inner opening. Therefore, the protective member 12 affixed to the front surface 10a of the semiconductor wafer 10 faces up. The dicing tape 16 is composed of a polyolefin sheet having a thickness of 95 μm in the illustrated embodiment. An UV tape having the property of reducing its adhesive strength by an external stimulus such as ultraviolet radiation is used as the dicing tape 16.

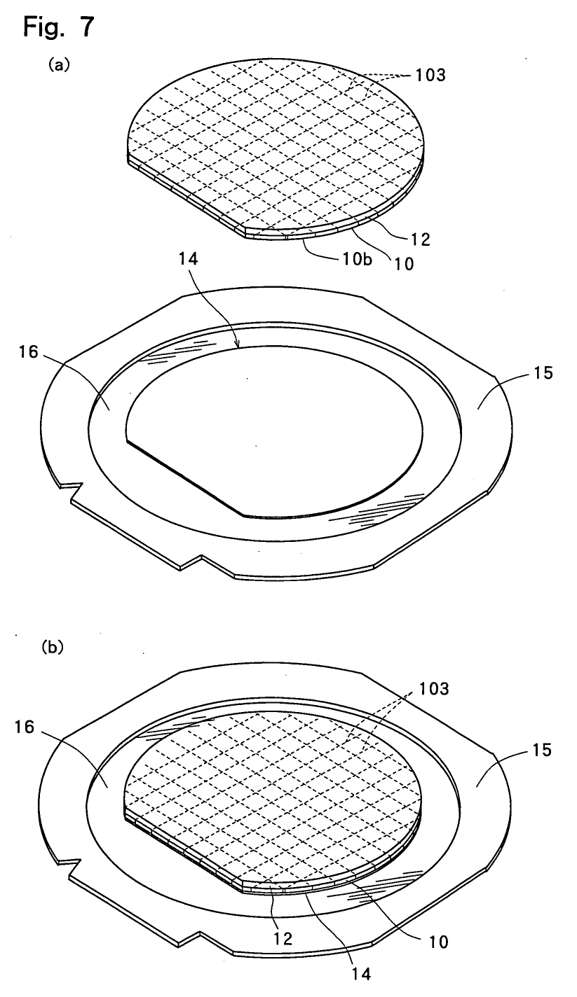

Another example of the above adhesive film affixing step and dicing tape affixing step will be described with reference to FIGS. 7(a) and 7(b).

In the example shown in FIGS. 7(a) and 7(b), a dicing tape with an adhesive film, which has been affixed onto the surface thereof before hand is used. That is, as shown in FIGS. 7(a) and 7(b), the adhesive film 14 affixed to the surface of the dicing tape 16 whose peripheral portion is mounted on the annular dicing frame 15 so as to cover its inner opening is put on the back surface 10b of the semiconductor wafer 10 which has been separated into individual semiconductor chips. At this point, the adhesive film 14 is pressed against the back surface 10b of the semiconductor wafer 10 under heating at 80 to 200° C. to be affixed to the back surface 10b. The above dicing tape 16 is composed of an elastic polyolefin sheet having a thickness of 95 μm. A dicing tape having an adhesive film (LE5000) manufactured by K.K. Rintekku may be used as the dicing tape having an adhesive film.

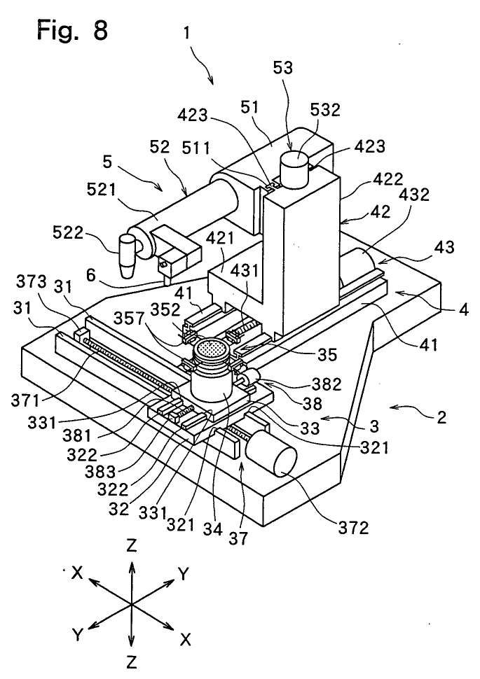

After the above adhesive film affixing step and the dicing tape affixing step, next comes the adhesive film melt-dividing step for melt-dividing the adhesive film 14 along the dividing grooves 103 by applying a laser beam having a wavelength absorbed by the adhesive film but not by the dicing tape to the adhesive film 14 affixed to the back surface 10b of the semiconductor wafer 10 which has been separated into individual semiconductor chips 100 along the above dividing grooves 103 from the dicing tape 16 side. This adhesive film melt-dividing step is carried out by a laser beam processing machine constituted according to the present invention shown in FIGS. 8 to 10.

FIG. 8 is a perspective view of a laser beam processing machine constituted according to the present invention. The laser beam processing machine 1 shown in FIG. 8 comprises a stationary base 2, a chuck table mechanism 3 for holding a workpiece, which is mounted on the stationary base 2 in such a manner that it can move in a processing-feed direction indicated by an arrow X, a laser beam application unit support mechanism 4 mounted on the stationary base 2 in such a manner that it can move in an indexing-feed direction indicated by an arrow Y perpendicular to the direction indicated by the arrow X, and a laser beam application unit 5 mounted on the laser beam application unit support mechanism 4 in such a manner that it can move in a direction indicated by an arrow Z.

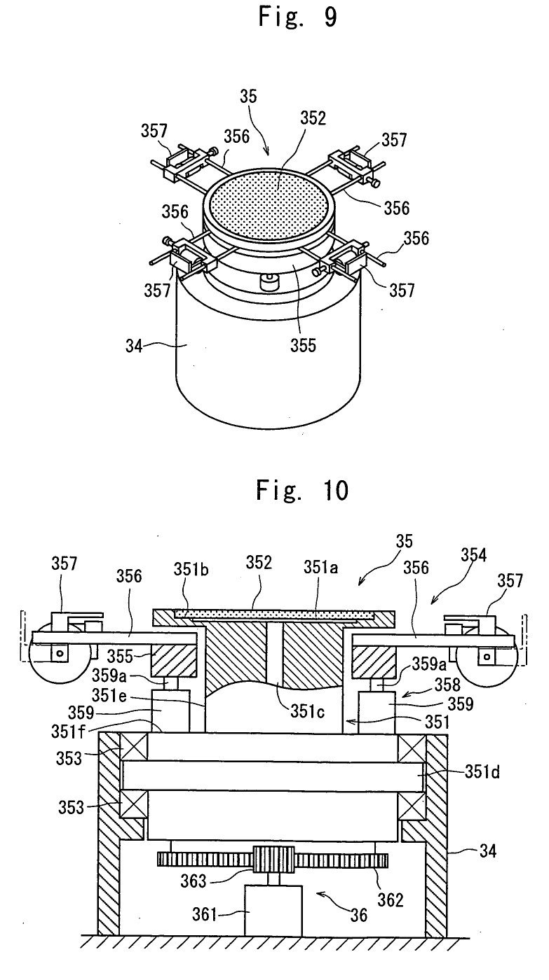

The above chuck table mechanism 3 comprises a pair of guide rails 31 and 31 mounted on the stationary base 2 and arranged parallel to each other in the processing-feed direction indicated by the arrow X, a first sliding block 32 mounted on the guide rails 31 and 31 in such a manner that it can move in the processing-feed direction indicated by the arrow X, a second sliding block 33 mounted on the first sliding block 32 in such a manner that it can move in the indexing-feed direction indicated by the arrow Y, a cylindrical support member 34 mounted on the second sliding block 33, and a chuck table 35 as a workpiece holding means rotatably supported by the cylindrical support member 34. This chuck table 35 will be described with reference to FIG. 9 and FIG. 10.

This chuck table 35 shown in FIG. 9 and FIG. 10 comprises a columnar body 351 and a workpiece holding member 352, which has gas permeability and is mounted on the top surface of the body 351. The body 351 is made of a metal material such as stainless steel or the like and a circular fitting recess portion 351a is formed in the top surface. This fitting recess portion 351a has an annular placing shelf 351b for placing the workpiece holding member 352 in the peripheral portion of the bottom surface. A suction path 351c open to the fitting recess portion 351a is formed in the body 351 and communicated with a suction means that is not shown. Therefore, when the suction means (not shown) is activated, negative pressure is exerted to the fitting recess portion 351a through the suction path 351c. An annular support flange portion 351d projecting in the radial direction is provided at the middle portion of the thus constituted chuck table 35. Bearings 353 and 353 are mounted on the top and bottom of the support flange portion 351d so that the chuck table 35 is rotatably supported by the above cylindrical support member 34 through the bearings 353 and 353. The chuck table 35 thus rotatably supported by the cylindrical support member 34 is suitably turned by a rotation drive means 36. The rotation drive means 36 comprises a pulse motor 361, a drive gear 362 fitted onto the drive shaft of the pulse motor 361 and an annular driven gear 363 that is installed below the body 351 constituting the chuck table 35 and is engaged with the drive gear 362.

A small-diameter portion 351e is formed at the upper portion of the body 351 constituting the chuck body 35. A frame holding means 354 for supporting the above annular frame 15 is provided outside the small-diameter portion 351e in the radial direction. The frame holding means 354 comprises an annular frame holding member 355 arranged around the small-diameter portion 351e, four holding arms 356 which are mounted on the top surface of the frame holding member 355 radially and extend outward in the radial direction, and four clamps 357 as a fixing means mounted on each of the end portions of the four holding arms 356. The frame holding means 354 constituted as described above fixes the above annular frame 15 placed on the four holding arms 356 by the four clamps 357.

The thus constituted frame holding means 354 is supported by a moving means 358 in such a manner that it can move in the axial direction (vertical direction). The moving means 358 which consists of a plurality of air cylinders 359 is mounted on a shoulder portion 351f forming the small-diameter portion 351e of the body 351 constituting the chuck table 35 in the illustrated embodiment. The piston rods 359a of the plurality of air cylinders 359 are connected to the undersurface of the above annular frame holding member 355. The moving means 358 thus consisting of the plurality of air cylinders 359 is connected to an air supply means (not shown) so that the frame holding means 354 is moved in the vertical direction between a standard position shown in FIG. 10 and an expansion position a predetermined distance below the standard portion by activating the air supply means that is not shown.

Returning to FIG. 8, the above first sliding block 32 has, on the undersurface, a pair of to-be-guided grooves 321 and 321 to be fitted to the above pair of guide rails 31 and 31 and has, on the top surface, a pair of guide rails 322 and 322 formed parallel to each other in the indexing-feed direction indicated by the arrow Y. The first sliding block 32 constituted as described above is constituted to move in the processing-feed direction indicated by the arrow X along the pair of guide rails 31 and 31 by fitting the to-be-guided grooves 321 and 321 to the pair of guide rails 31 and 31. The chuck table mechanism 3 in the illustrated embodiment comprises a processing-processing-feed means 37 for moving the first sliding block 32 along the pair of guide rails 31 and 31 in the processing-feed direction indicated by the arrow X. The processing-feed means 37 comprises a male screw rod 371 arranged between the above pair of guide rails 31 and 31 parallel thereto, and a drive source such as a pulse motor 372 for rotary-driving the male screw rod 371. The male screw rod 371 is, at its one end, rotatably supported to a bearing block 373 fixed on the above stationary base 2 and is, at the other end, transmission-coupled to the output shaft of the above pulse motor 372. The male screw rod 371 is screwed into a threaded through-hole formed in a female screw block (not shown) projecting from the undersurface of the center portion of the first sliding block 32. Therefore, by driving the male screw rod 371 in a normal direction or reverse direction with the pulse motor 372, the first sliding block 32 is moved along the guide rails 31 and 31 in the processing-feed direction indicated by the arrow X.

The above second sliding block 33 has, on the undersurface, a pair of to-be-guided grooves 331 and 331 to be fitted to the pair of guide rails 322 and 322 formed on the top surface of the above first sliding block 32 and can move in the indexing-feed direction indicated by the arrow Y by fitting the to-be-guided grooves 331 and 331 to the pair of guide rails 322 and 322. The chuck table mechanism 3 in the illustrated embodiment comprises a first indexing-feed means 38 for moving the second sliding block 33 in the indexing-feed direction indicated by the arrow Y along the pair of guide rails 322 and 322 formed on the first sliding block 32. The first indexing-feed means 38 comprises a male screw rod 381, which is arranged between the above pair of guide rails 322 and 322 parallel thereto, and a drive source such as a pulse motor 382 for rotary-driving the male screw rod 381. The male screw rod 381 is, at its one end, rotatably supported to a bearing block 383 fixed on the top surface of the above first sliding block 32 and is, at the other end, transmission-coupled to the output shaft of the above pulse motor 382. The male screw rod 381 is screwed into a threaded through-hole formed in a female screw block (not shown) projecting from the undersurface of the center portion of the second sliding block 33. Therefore, by driving the male screw rod 381 in a normal direction or reverse direction with the pulse motor 382, the second sliding block 33 is moved along the guide rails 322 and 322 in the indexing-feed direction indicated by the arrow Y.

The above laser beam application unit support mechanism 4 comprises a pair of guide rails 41 and 41, which are mounted on the stationary base 2 and arranged parallel to each other in the indexing-feed direction indicated by the arrow Y, and a movable support base 42 mounted on the guide rails 41 and 41 in such a manner that it can move in the direction indicated by the arrow Y. This movable support base 42 comprises a movable support portion 421 movably mounted on the guide rails 41 and 41 and a mounting portion 422 mounted on the movable support portion 421. The mounting portion 422 is provided with a pair of guide rails 423 and 423 extending parallel to each other in the direction indicated by the arrow Z on one of its flanks. The laser beam application unit support mechanism 4 in the illustrated embodiment comprises a second indexing-feed means 43 for moving the movable support base 42 along the pair of guide rails 41 and 41 in the indexing-feed direction indicated by the arrow Y. This second indexing-feed means 43 comprises a male screw rod 431 that is arranged between the above pair of guide rails 41 and 41 parallel thereto, and a drive source such as a pulse motor 432 for rotary-driving the male screw rod 431. The male screw rod 431 is, at its one end, rotatably supported to a bearing block (not shown) fixed on the above stationary base 2 and is, at the other end, transmission-coupled to the output shaft of the above pulse motor 432. The male screw rod 431 is screwed into a threaded through-hole formed in a female screw block (not shown) projecting from the undersurface of the center portion of the movable support portion 421 constituting the movable support base 42. Therefore, by driving the male screw rod 431 in a normal direction or reverse direction with the pulse motor 432, the movable support base 42 is moved along the guide rails 41 and 41 in the indexing-feed direction indicated by the arrow Y.

The laser beam application unit 5 in the illustrated embodiment comprises a unit holder 51 and a laser beam application means 52 secured to the unit holder 51. The unit holder 51 has a pair of to-be-guided grooves 511 and 511 to be slidably fitted to the pair of guide rails 423 and 423 on the above mounting portion 422 and is supported in such a manner that it can move in the direction indicated by the arrow Z by fitting the guide grooves 511 and 511 to the above guide rails 423 and 423, respectively.

The illustrated laser beam application means 52 applies a pulse laser beam from a condenser 522 mounted on the end of a cylindrical casing 521 arranged substantially horizontally. An image pick-up means 6 for detecting the area to be processed by the above laser beam application means 52 is mounted on the fore-end of the casing 521 constituting the above laser beam application means 52. This image pick-up means 6 comprises an illuminating means for illuminating the workpiece, an optical system for capturing the area illuminated by the illuminating means, and an image pick-up device (CCD) for picking up an image captured by the optical system. An image signal is sent to a control means that is not shown.

The laser beam application unit 5 in the illustrated embodiment comprises a moving means 53 for moving the unit holder 51 along the pair of guide rails 423 and 423 in the direction indicated by the arrow Z. The moving means 53 includes a male screw rod (not shown) arranged between the pair of guide rails 423 and 423 and a drive source such as a pulse motor 532 for rotary-driving the male screw rod. By driving the male screw rod (not shown) in a normal direction or reverse direction with the pulse motor 532, the unit holder 51 and the laser beam application means 52 are moved along the guide rails 423 and 423 in the direction indicated by the arrow Z. In the illustrated embodiment, the laser beam application means 52 is moved up by driving the pulse motor 532 in a normal direction and moved down by driving the pulse motor 532 in the reverse direction.

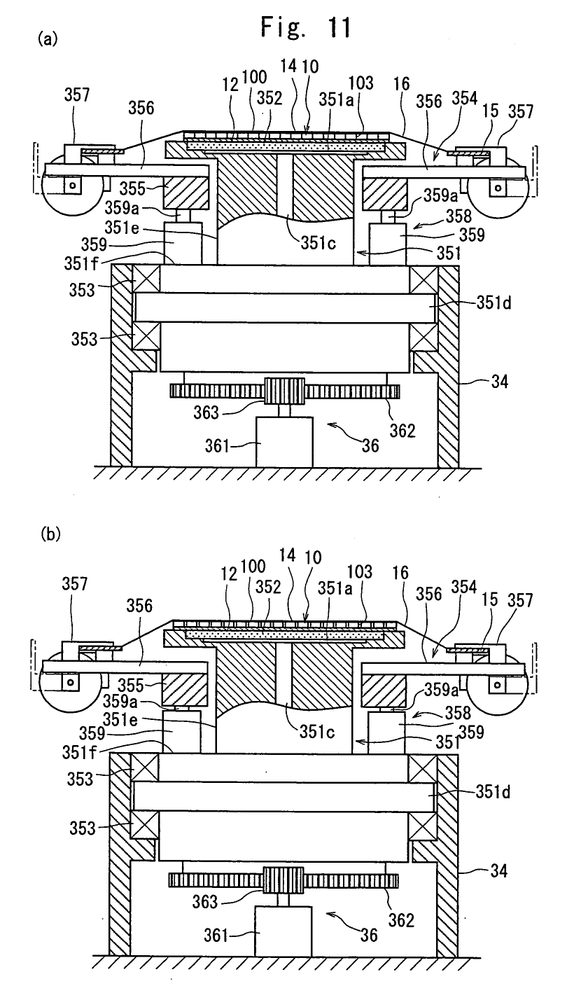

A description is subsequently given of the adhesive film melt-dividing step which is carried out by using the above laser beam processing machine 1 with reference to FIGS. 11(a) and 11(b) to 13.

In the adhesive film melt-dividing step, the semiconductor wafer 10 having the adhesive film 14 on the surface of the dicing tape 16, which has been subjected to the above adhesive film affixing step and the dicing tape affixing step, is placed on the workpiece holding member 352 of the chuck table 35 in such a manner that the protective member 12 side of the semiconductor wafer 10 faces down, as shown in FIG. 11(a). The annular dicing frame 15 having the dicing tape 16 mounted thereon is placed on the four holding arms 356 of the frame holding means 354, and fixed on the four holding arms 356 by the four clamps 357. The plurality of air cylinders 359 of the moving means 358 are then activated to move down the frame holding means 354 from the standard position shown in FIG. 11(a) to the expansion position shown in FIG. 11(b). As a result, the extensible dicing tape 16 is expanded, whereby the adhesive film 14 affixed to the dicing tape 16 is also expanded and the width of the dividing grooves 103 of the semiconductor wafer 10 having the adhesive film 14 affixed thereto is increased, thereby expanding the interval between adjacent semiconductor chips 100 (tape expanding step). After the tape expanding step is carried out, the semiconductor wafer 10 placed on the workpiece holding member 352 of the chuck table 35 is suction-held via the protective member 12 by activating the suction means that is not shown. The chuck table 35 suction-holding the semiconductor wafer 10 as described above is moved along the guide rails 31 and 31 by the operation of the processing-feed means 37 and positioned right below the image pick-up means 6 mounted on the laser beam application unit 5.

After the chuck table 35 is positioned right below the image pick-up means 6, alignment work for detecting the area to be processed of the semiconductor wafer 10 is carried out by the image pick-up means 6 and the control means that is not shown. That is, the image pick-up means 6 and the control means (not shown) carry out image processing such as pattern matching, etc. to align a dividing groove 103 formed in the predetermined direction of the semiconductor wafer 10 with the condenser 522 of the laser beam application unit 5 for applying a laser beam along the dividing groove 103, thereby performing the alignment of a laser beam application position. Further, the alignment of the laser beam application position is also carried out on dividing grooves 103 formed on the semiconductor wafer 10 in a direction perpendicular to the predetermined direction. At this point, when the adhesive film 14 affixed to the back surface 10b of the semiconductor wafer 10 separated into individual semiconductor chips and the dicing tape 16 are not transparent and the dividing grooves 103 cannot be confirmed, an image pick-up means which is constituted by an infrared illuminating means, an optical system for capturing infrared radiation, an image pick-up device (infrared CCD) for outputting an electric signal corresponding to the infrared radiation, etc. is used as the image pick-up means 6 to pick up images of the dividing grooves 103 through the adhesive film 14 and the dicing tape 16.

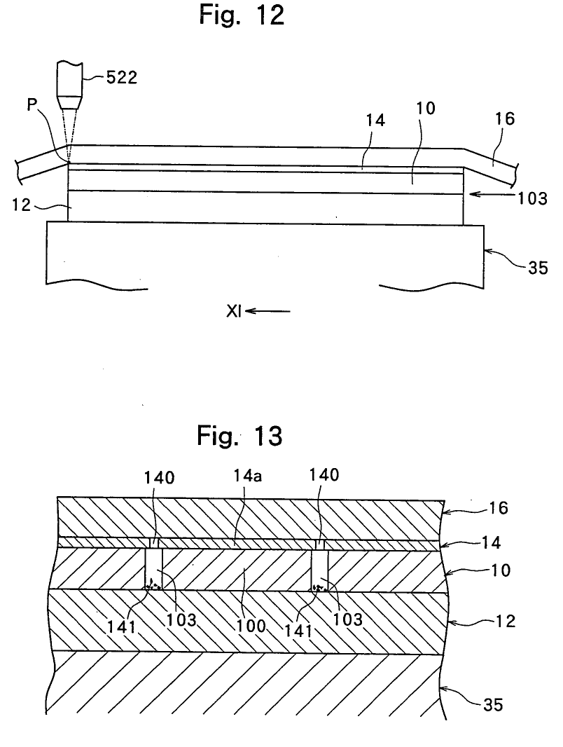

After the alignment of the laser beam application position is carried out, the chuck table 35 is moved to a laser beam application area where the condenser 522 of the laser beam application means 52 for applying a laser beam is located so as to bring one end (left end in FIG. 12) of the predetermined dividing groove 103 to a position right below the condenser 522 of the laser beam application means 52, as shown in FIG. 12. The chuck table 35, that is, the semiconductor wafer 10, is then moved in the direction indicated by the arrow X1 in FIG. 12 at a predetermined feed rate while a laser beam having a wavelength absorbed by the adhesive film 14 but not by the dicing tape 16 is applied from the condenser 522. When the other end (right end in FIG. 12) of the dividing groove 103 reaches the application position of the condenser 522, the application of the pulse laser beam is suspended and the movement of the chuck table 35, that is, the semiconductor wafer 10 is stopped. At this point, the focusing point P (point where the spot of a converged beam is formed) of the pulse laser beam applied from the condenser 522 of the laser beam application means 52 is set to a position near the top surface of the adhesive film 14. The wavelength of this laser beam is set to 355 nm, which is absorbed by a polyimide-based resin, epoxy-based resin or acrylic resin sheet constituting the adhesive film 14 but not by a polyolefin sheet constituting the dicing tape 16. However, it is suitably set according to the relationship between the material selected for the dicing tape and the material selected for the adhesive film. As a result, the adhesive film 14 is melt-divided along the dividing grooves 103 by the energy of the laser beam passing through the dicing tape 16, whereby a break line 140 is formed as shown in FIG. 13 (adhesive film melt-dividing step).

Although the adhesive film 14 is molten at the time of the fusion of the adhesive film 14 to produce debris 141 in the above adhesive film melt-dividing step, as the width of the dividing grooves 103 of the semiconductor wafer 10 is increased to expand the interval between adjacent semiconductor chips 100 as described above, adjacent semiconductor chips 100 are not bonded together by the debris 141. Further, as the width of the dividing grooves 103 of the semiconductor wafer 10 is increased to expand the interval between adjacent semiconductor chips 100 in the above adhesive film melt-dividing step, the semiconductor chips 100 is not irradiated by the laser beam. Since the adhesive film 14 is affixed to the dicing tape 16, the debris 141 molten by the laser beam are not scattered and do not contaminate the semiconductor chips 100.

The processing conditions in the above adhesive film melt-dividing step are set as follows, for example.

Type of laser beam: solid-state laser (YVO4 laser, YAG laser) Wavelength: 355 nm

Oscillation method: pulse oscillation

Pulse width: 12 ns

Focusing spot diameter: 9.2 μm

Repetition frequency: 50 kHz

Average output: 2 W

Processing-feed rate: 500 mm/sec

After the break line 140 is formed in the adhesive film 14 along the dividing grooves 103 in the predetermined direction as described above, the chuck table 35 is moved a distance corresponding to the interval between dividing grooves 103 in the indexing-feed direction indicated by the arrow Y (see FIG. 8) to carry out the above processing-feeding again. After the above processing-feeding and index-feeding are carried out on all the dividing grooves 103 formed in the predetermined direction, the chuck table 35 is turned at 90° to carry out the above processing-feeding and index-feeding on dividing grooves 103 formed in a direction perpendicular to the above predetermined direction. Thereby, the adhesive film 14 is melt-divided into adhesive film pieces 14a affixed to each of the semiconductor chips 100 separated from one another by the dividing grooves 103. Since the plurality of semiconductor chips 100 separated from one another are put on the dicing tape 16 and the protective member 12 is affixed to the front surfaces of the semiconductor chips 100 even when the adhesive film 14 affixed to the back surfaces of the semiconductor chips 100 is melt-divided into adhesive film pieces 14a for the semiconductor chips 100, the semiconductor chips 100 and the adhesive film pieces 14a do not fall apart and the form of the semiconductor wafer 10 is maintained.

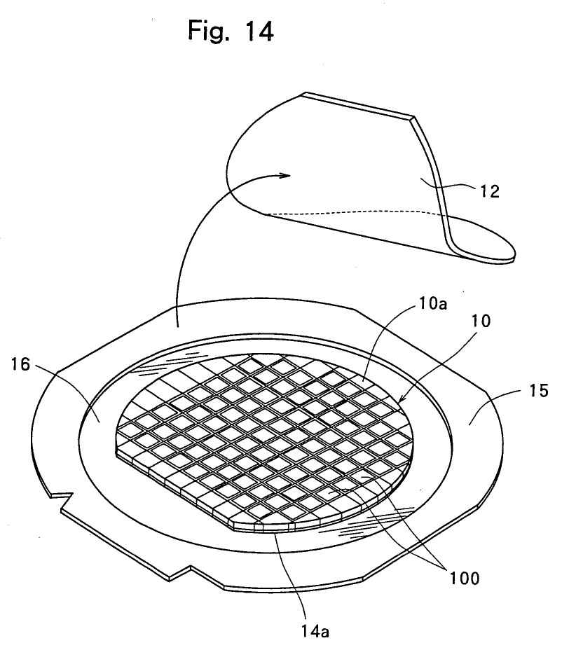

The above adhesive film melt-dividing step is followed by the step of removing the protective member 12 affixed to the front surfaces of the semiconductor chips 100. That is, as shown in FIG. 14, the dicing frame 15 mounting the dicing tape 16 is turned upside down so that the protective member 12 affixed to the front surface 10a of the semiconductor wafer 10 separated into individual semiconductor chips 100 faces up to be removed from the front surface 10a of the semiconductor wafer 10. Since the protective member removing step is carried out after the adhesive film melt-dividing step as described above, even when debris are produced in the adhesive film melt-dividing step, they do not adhere to the front surface 10a of the semiconductor wafer 10.

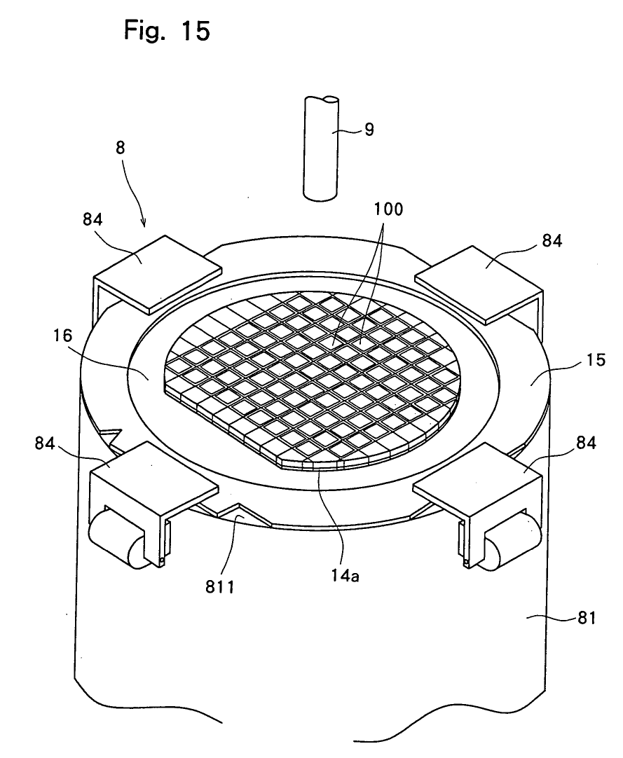

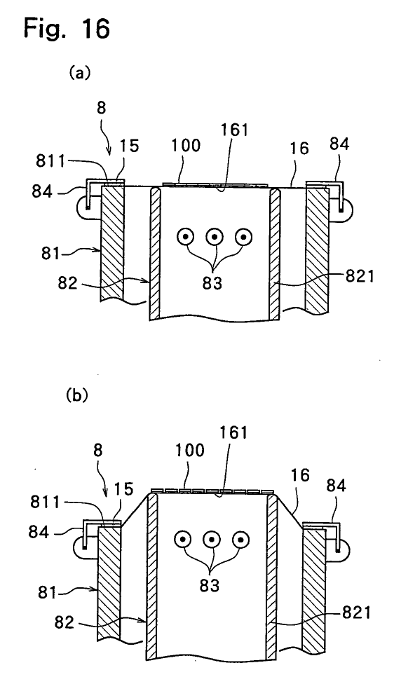

After the above protective member removing step, next comes the step of disengaging the semiconductor chips 100 having the adhesive film piece 14a affixed thereto from the dicing tape 16. This semiconductor chip disengaging step is carried out by a pick-up apparatus 8 shown in FIG. 15 and FIGS. 16(a) and 16(b). The pick-up apparatus 8 will be described hereinafter. The illustrated pick-up apparatus 8 comprises a cylindrical base 81 having a placing surface 811 for placing the above dicing frame 15 and an expanding means 82 for expanding the dicing tape 16 that is concentrically arranged in the base 81 and mounted on the dicing frame 15. The expanding means 82 has a cylindrical expanding member 821 for supporting an area 161 where the plurality of semiconductor chips 100 of the above dicing tape 16 are existent. This expanding member 821 can be moved vertically (in the axial direction of the cylindrical base 81) between a standard position shown in FIG. 16(a) and an expansion position shown in FIG. 16(b) by a lifting means that is not shown. Ultraviolet lamps 83 are installed in the expansion member 821 in the illustrated embodiment.

The semiconductor chip disengaging step which is carried out by using the above pick-up apparatus 8 will be described with reference to FIG. 15 and FIGS. 16(a) and 16(b).

The dicing frame 15 supporting the plurality of semiconductor chips 100 on the extensible dicing tape 16 mounted thereon (the adhesive film pieces 14a affixed to the back surfaces are supported on the top surface of the dicing tape 16) is placed on the placing surface 811 of the cylindrical base 81, as shown in FIG. 15 and FIG. 16(a) and fixed on the base 81 by clamps 84. Then, as shown in FIG. 16(b), the expansion member 821 of the expanding means 82 supporting the area 161 where the plurality of semiconductor chips 100 of the above dicing tape 16 are existent is moved up to the expansion position shown in FIG. 16(b) from the standard portion shown in FIG. 16(a) by the lift means that is not shown. As a result, the extensible dicing tape 16 is expanded and consequently, a gap is formed between the dicing tape 16 and the adhesive film pieces 14a mounted on the semiconductor chips 100, thereby reducing adhesion. Therefore, the semiconductor chips 100 having the adhesive film piece 14a affixed thereto can be easily disengaged from the dicing tape 16 and at the same time, a space is formed between the individual semiconductor chips 100 and the adhesive film pieces 14a affixed to the semiconductor chips 100.

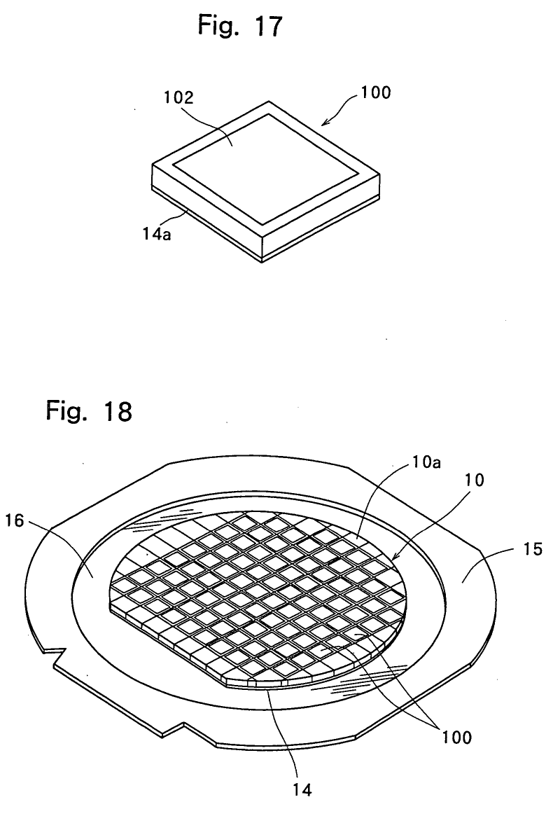

The individual semiconductor chips 100 are then disengaged from the top surface of the dicing tape 16 by activating a pick-up collet arranged above the pick-up apparatus 8, as shown in FIG. 15 and carried onto a tray that is not shown. At this point, the ultraviolet lamps 83 installed in the expansion member 821 are turned onto irradiate ultraviolet radiation to the dicing tape 16 so as to reduce the adhesive strength of the dicing tape 16. As a result, the semiconductor chips 100 can be more easily disengaged from the dicing tape 16. The semiconductor chips 100 thus disengaged from the dicing tape 16 have are in a state of the adhesive film piece 14a being affixed to the back surface, as shown in FIG. 17. Therefore, the semiconductor chips 100 having the adhesive film piece 14a mounted on the back surface are obtained.

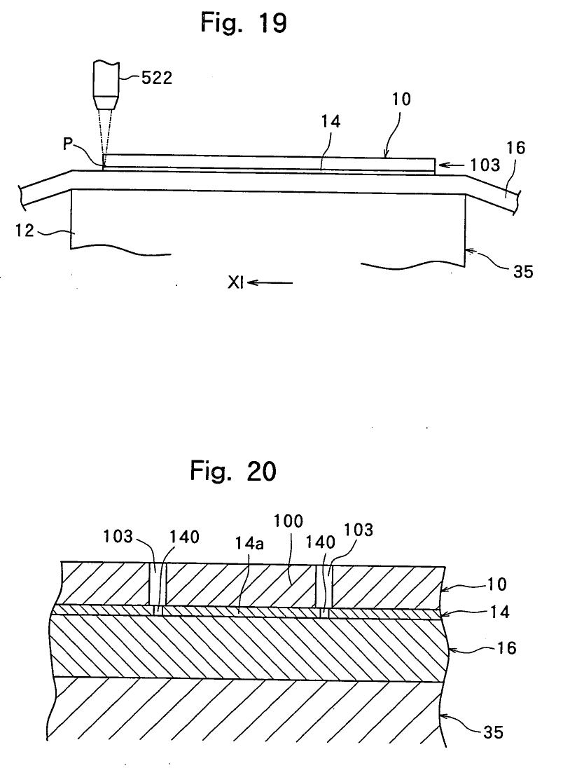

A description is subsequently given of another example of the dicing tape affixing step and the adhesive film melt-dividing step with reference to FIG. 18, FIG. 19 and FIG. 20.

In the dicing tape affixing step shown in FIG. 18, the adhesive film 14 side of the semiconductor wafer 10 having the adhesive film 14 affixed to the back surface, which has been subjected to the above-mentioned dividing groove exposing step and the adhesive film affixing step, is bonded to the surface of the dicing tape 16 mounted on the annular dicing frame 15. Accordingly, the front surface 10a of the semiconductor wafer 10 faces up.

The adhesive film melt-dividing step comes after the dicing tape affixing step shown in FIG. 18. That is, the dicing tape 16 on which the adhesive film 14 side of the semiconductor wafer 10 is put is placed on the chuck table 35 of the above laser beam processing machine 1 as shown in FIG. 19 to carry out the above tape expanding step. After the above alignment of the laser beam application position, as shown in FIG. 19, one end (left end in FIG. 19) of a predetermined dividing groove 103 is brought to a position right below the condenser 522 of the laser beam application means 52. The chuck table 35, that is, the semiconductor wafer 10 is then moved in the direction indicated by the arrow X1 in FIG. 19 at a predetermined feed rate while a laser beam is applied from the condenser 522. When the other end (right end in FIG. 19) of the dividing groove 103 reaches the application position of the condenser 522, the application of the pulse laser beam is suspended and the movement of the chuck table 35, that is, the semiconductor wafer 10 is stopped. At this point, the pulse laser beam from the condenser 522 of the laser beam application means 52 is applied to the adhesive film 14 through the dividing groove 103 from the front surface 10a side of the semiconductor wafer 10. As a result, the adhesive film 14 is melt-divided along the dividing groove 103 by the energy of the laser beam to form a break line 140, as shown in FIG. 20. In this adhesive film melt-dividing step, as the width of the dividing grooves 103 of the semiconductor wafer 10 is increased by carrying out the above tape expanding step to expand the interval between adjacent semiconductor chips 100, the laser beam can be surely applied to the adhesive film 14 through the dividing grooves 103.

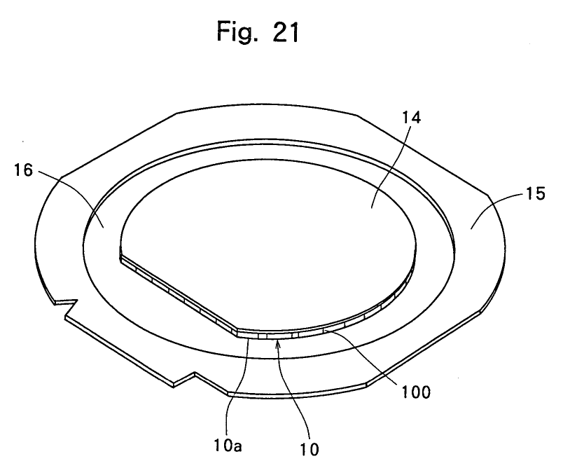

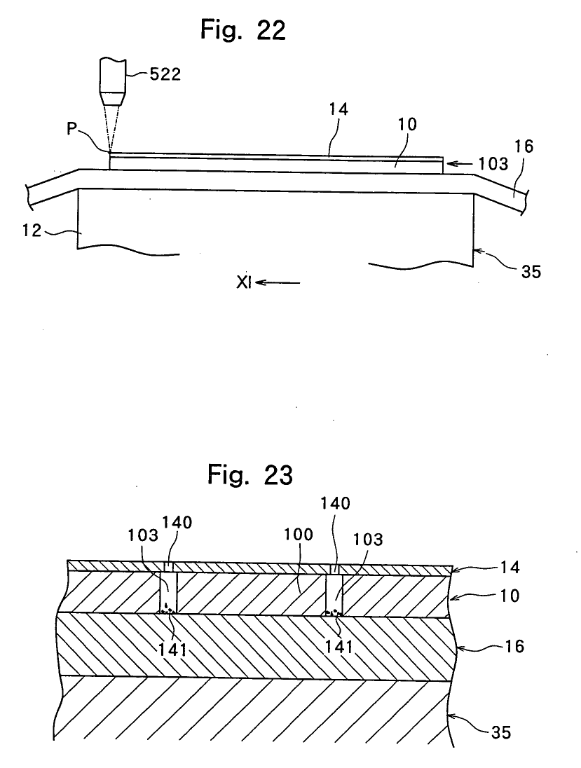

A description is subsequently given of still another example of the above dicing tape affixing step and the adhesive film melt-dividing step with reference to FIG. 21, FIG. 22 and FIG. 23.

In the dicing tape affixing step shown in FIG. 21, the front surface 10a side of the semiconductor wafer 10 having the adhesive film 14 affixed to the back surface lob, which has been subjected to the above-mentioned dividing groove exposing step and the adhesive film affixing step, is put on the surface of the dicing tape 16 mounted on the annular dicing frame 15. Therefore, the adhesive film 14 affixed to the back surface 10b of the semiconductor wafer 10 faces up.

The adhesive film melt-dividing step comes after the dicing tape affixing step shown in FIG. 21. That is, as shown in FIG. 22, the dicing tape 16 affixed to the front surface 10a side of the semiconductor wafer 10 is placed on the chuck table 35 of the above-described laser beam processing machine 1 to carry out the above tape expanding step. After the alignment of the above laser beam application position, as shown in FIG. 22, one end (left end in FIG. 22) of a predetermined dividing groove 103 is brought to a position right below the condenser 524 of the laser beam application means 52. The chuck table 35, that is, the semiconductor wafer 10 is then moved in the direction indicated by the arrow X1 in FIG. 22 at a predetermined feed rate while a laser beam is applied from the condenser 522. When the other end (right end in FIG. 22) of the dividing groove 103 reaches the application position of the condenser 522, the application of the pulse laser beam is suspended and the movement of the chuck table 35, that is, the semiconductor wafer 10 is stopped. At this point, the pulse laser beam from the condenser 522 of the laser beam application means 52 is applied to the adhesive film 14 along the dividing groove 103 from the adhesive film 14 side. As a result, the adhesive film 14 is melt-divided along the dividing groove 103 by the energy of the laser beam to form a break line 140, as shown in FIG. 23. Although the adhesive film 14 is molten in this adhesive film melt-dividing step to produce debris 141, the width of the dividing grooves 103 of the semiconductor wafer 10 is increased to expand the interval between adjacent semiconductor chips 100 as described above. Therefore, adjacent semiconductor chips 100 are not bonded together by the debris 141.

What is claimed is:

1. A laser processing method for melt-dividing an adhesive film for die bonding affixed to the back surface of a semiconductor wafer which has been separated into a plurality of semiconductor chips and which is put on an extensible dicing tape mounted on an annular frame along dividing grooves for separating the plurality of semiconductor chips from one another, comprising the steps of:
a tape expanding step for expanding the dicing tape affixed to the semiconductor wafer to increase the width of the dividing grooves for separating the plurality of semiconductor chips from one another; and
an adhesive film melt-dividing step for melt-dividing the adhesive film along the dividing grooves by applying a laser beam to the adhesive film along the dividing grooves in a state where the width of the dividing grooves for separating the plurality of semiconductor chips from one another has been increased.

2. A laser beam processing machine comprising a chuck table mechanism for holding a workpiece put on a dicing tape mounted on an annular frame, a laser beam application means for applying a laser beam to the work piece held on the chuck table mechanism, and a processing-feed means for moving the laser beam application means and the chuck table relative to each other, wherein
the chuck table mechanism comprises a chuck table for holding the workpiece, a frame holding means for holding the annular frame, that is arranged around the chuck table, and a moving means for moving the frame holding means and the chuck table relative to each other in the axial direction.
